(19) United States
(12) Patent Application Publication
(10) Pub. No.: US 2007/0168838 A1
(43) Pub. Date: Jul. 19, 2007

(54) Reproduction apparatus and method for reproducing a unique medium identifier

(75) Inventors: Petrus Henricus Cornelius Bentvelsen, Eindhoven (NL); Pope Ijtsma, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/597,760

(22) PCT Filed: Feb. 2, 2005
(86) PCT No.: PCT/IB05/50434

§ 371 Date: Aug. 7, 2006

(30) Foreign Application Priority Data
Feb. 12, 2004 (EP) 04100528.1

(51) Int. Cl. G11C 29/00

(52) U.S. Cl. 714/770

(57) ABSTRACT

The present invention relates to reproducing a unique identifier (ID) from a record carrier (5), a data which has area for storing data and a defect management area for storing data reallocated from defective sectors and for storing reallocation information. To prevent users from copying the unique identifier a reproduction apparatus is proposed comprising:—a reallocation information reading means (7) for reading reallocation information from said defect management area marking a first predetermined non-defective sector in said data area as defective and as reallocated to a second sector in said defect management area,—a data reading means (6, 8) for reading a first data unit from said first sector and for reading a second data unit from said second sector, and —an evaluation means 10) for evaluating said first data unit and said second data unit by comparison and/or combination to derive said unique identifier(ID).

The present invention relates to a reproduction apparatus and a corresponding reproduction method for reproducing a unique identifier ID from a record carrier, said record carrier having a data area for storing data and a defect management area for storing data reallocated from defective sectors of said data area and for storing reallocation information. Further, the present invention relates to a recording apparatus and a corresponding recording method, to a record carrier and to a computer program for implementing said methods on a computer.

On media it is required for various reasons, such as copy protection or internet control for distribution, to have a unique identifier, for instance a unique number, that can be used as an identification of an original record carrier and/or as a content decryption key. The identifier may be disc-unique, as is usually, but not necessarily, the case for recordable or rewritable discs where the unique identifier is written, e.g. the first time the disc enters a drive, or batch-unique, as is usually the case for pre-pressed discs.

Most of the systems to record a unique identifier on a record carrier suffer from one or more of the following drawbacks: special equipment is required during the production process to record the unique identifier, a special decoder is needed in the drive to read the unique identifier and/or the unique identifier can be copied easily using a raw copy method.

U.S. Pat. No. 5,930,825 discloses a method and apparatus for preventing unauthorized use by comparing medium identifications. A recording medium has a medium ID information storing area in a user data area for identification of the recording medium on which software/data is recorded. An original medium ID information storing area, which is regarded as a defect area, is also included in the user data area for storing original medium ID information, wherein the original medium ID information is compared with the medium ID information to judge unauthorized use of the software/data.

According to the solution disclosed in U.S. Pat. No. 5,930,825 the logical clusters are distributed non-linearly over the physical clusters in the user data area. Reconstructing the look-up table of the logical clusters versus the physical clusters during read-back retrieves the key. The look-up table is also stored in the file system on the disc. Examination of the file system will reveal the hidden key, while copying the data on the disc including the file system metadata will also copy the hidden key.

It is an object of the present invention to provide a reproduction apparatus and method for reproducing a unique identifier by which the above mentioned drawbacks can be avoided and by which the unique identifier cannot be retrieved or copied easily. Further, a corresponding recording apparatus and method, a record carrier and a computer program for implementing said methods shall be provided.

The object is achieved according to the present invention by a reproduction apparatus as claimed in claim 1.

The object is also achieved by a recording apparatus as claimed in claim 11.

Corresponding methods are defined in claims 10 and 12. A record carrier according to the present invention having a data area and a defect management area is defined in claim 13. A computer program for implementing said methods is defined in claim 15.

The present invention is based on the idea to make use of the defect management system in the drive, which is, preferably, a Mount Rainier compatible drive. This has the advantage that, at least for BD and DVD, a true raw copy can not be made because the defect management information stored on the record carrier can usually not be copied. For instance, in the Mount Rainier format, the defect management structures (in particular the reallocation information preferably stored as a defect table) are located in the lead-in area, and a copy of this structure is located at the end of the data area (in the case of BD-, DVD- and CD-Mount Rainier).

According to the invention at least one sector (which term shall be understood as either physical sector or ECC-block) is reallocated. The contents of the logical sector at its original position in the data area and its reallocated position in the defect management area are preferably made different. Both sectors are read by the reproduction apparatus and evaluated in order to derive the unique identifier by a comparison and/or combination of the content of said sectors. For the user, for instance a host of a computer into which the reproduction apparatus is incorporated, it is not possible to manipulate reallocations since this is done autonomously by the drive, i.e. the reproduction apparatus.

Compared to the method and apparatus disclosed in U.S. Pat. No. 5,930,825, physical addresses are replaced by other physical addresses instead of just mixing up physical addresses as a function of logical addresses. Further, the rallocation information, e.g. a replacement table, is not managed by the file system, but deeper: it is managed by the drive (at least in case of using a Mount Rainier system). In Mount Rainier defect management for CD and DVD, there is no possibility for the host to modify the lookup table, at least not with the multimedia command (MMC) command set. Even if a file system (e.g. UDF1.5) allows defect management by the file system, the invention is also applicable; however, in this case, the unique identifier can be copied more easily.

Preferred embodiments of the invention are defined in the dependent claims. Different embodiments of the evaluation means for deriving the unique identifier are defined in claims 2 to 4. Generally, any combination of the first data unit and the second data unit can be used to derive the unique identifier. Examples are arithmetic operations, such as an addition or subtraction of the data, Boolean operations, such as an exclusive OR operation of the data, or the use of a scrambling algorithm. Further, one of the data units can be used as a decryption key to decrypt the other data unit, or one data unit can be used as a map to point to byte positions in the other data unit which contain the unique identifier. In a simple embodiment, only the data from one of the data units can be used as unique identifier, while the other data unit can be ignored and can thus be used to store user data. It shall be understood that this last embodiment is included by the term “combination” used in claim 1.

Instead of using the contents of the sectors at the original position and the reallocation position, also the reallocation pattern can be used to derive the unique identifier. Therefore, in another embodiment, the reading means is operative for reading a plurality of first data units from a plurality of first sectors and for reading a plurality of second data units from a plurality of second sectors, and the evaluation means is operative for deriving the unique identifier by comparing said first data units with the respective second data units and for obtaining the unique identifier from the result of said comparison.

The reallocation pattern can thus be used in many ways. In a simple embodiment a number of sectors at given locations is either reallocated or not. If it is reallocated, this information shall be interpreted as a bit value “1”, otherwise it shall be interpreted as bit value “0” (or vice versa). Whether the data in the original position (i.e. the first data units in the first sectors) differ from the data in the reallocated positions (i.e. the second data in the second data positions), can be determined by the user by comparing the first with the respective (reallocated) second data units. Another method is to look in the copy of the reallocation table, if present on the record carrier and if available to the user.

In order to enable the reproduction apparatus to know which sectors to read and which evaluation function to use for obtaining the unique identifier, a memory means is provided in a preferred embodiment of the reproduction apparatus storing this information. Thus, the recording apparatus and the reproduction apparatus agree beforehand about the addresses of sectors and the evaluation function, which information can, for instance, be part of a standard.

In an alternative embodiment this information is stored on the record carrier, i.e. it can vary and can be selected during recording. The reproduction apparatus then comprises an appropriate evaluation information reading means.

In order to read the first and second data unit from the record carrier it is preferred that the first data unit is read by a streaming read command and that the second data unit is read by a logical read command. The read commands are multimedia commands from a MMC set, which is a standardized command set for host-drive interface. These read commands are thus issued by the host application. This has the advantage that the unique identifier, or, more precisely, the data units for deriving the unique identifier, can be read by the host, but not modified, because the defect management functionality is done solely by the drive, while the host does not have write access to the defect tables. By use of available commands from the MMC set as proposed in this embodiment, there is no need to change anything for read-back and reproduction of the unique identifier.

Another embodiment, preferably within the Mount Rainier format, makes use of the general application area (GAA) in combination with the defect management area. The GAA and the defect management area can not be available at the same time. Both areas make use of the same logical sector addressing, i.e. there are duplicate sector addresses, and the drive has to be set to either GAA addressing or defect management area addressing. Sectors with information for deriving the unique identifier, but with different content in the GAA and in the defect management area can be put in the same logical sectors of the two different areas. This information can thus only be retrieved, if the disc is inserted in a Mount Rainier drive adapted according to the present invention.

Although the defect management system is normally designed exclusively for rewritable media, the defect management format can also be applied on read-only media and recordable media as well, i.e. the present invention can generally be used with all kinds of optical record carriers. Further, the recording of the first and second data unit and the reallocation information could both be done during mastering or in the drive, e.g. the first time the record carrier is entered into a drive.

It should be noted that in case of using the different read processes, these should yield different results from which the unique identifier is composed. Thus, in this embodiment, it is preferred, but not mandatory, that the content of the first and second data units is made different. However, in the embodiment using the reallocation pattern for deriving the unique identifier, the content can be equal or different.

The invention will now be explained in more detail with reference to the drawings in which

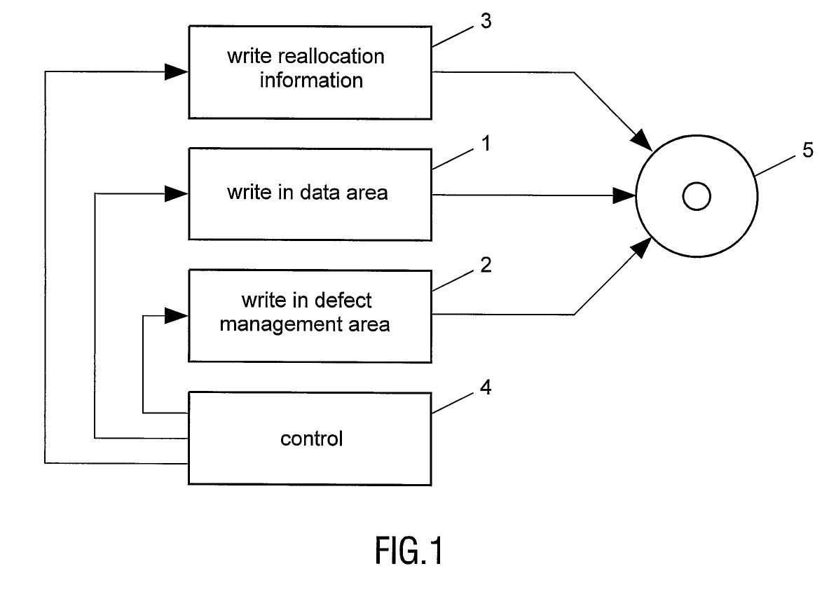

FIG. 1 shows a block diagram of a recording apparatus according to the invention,

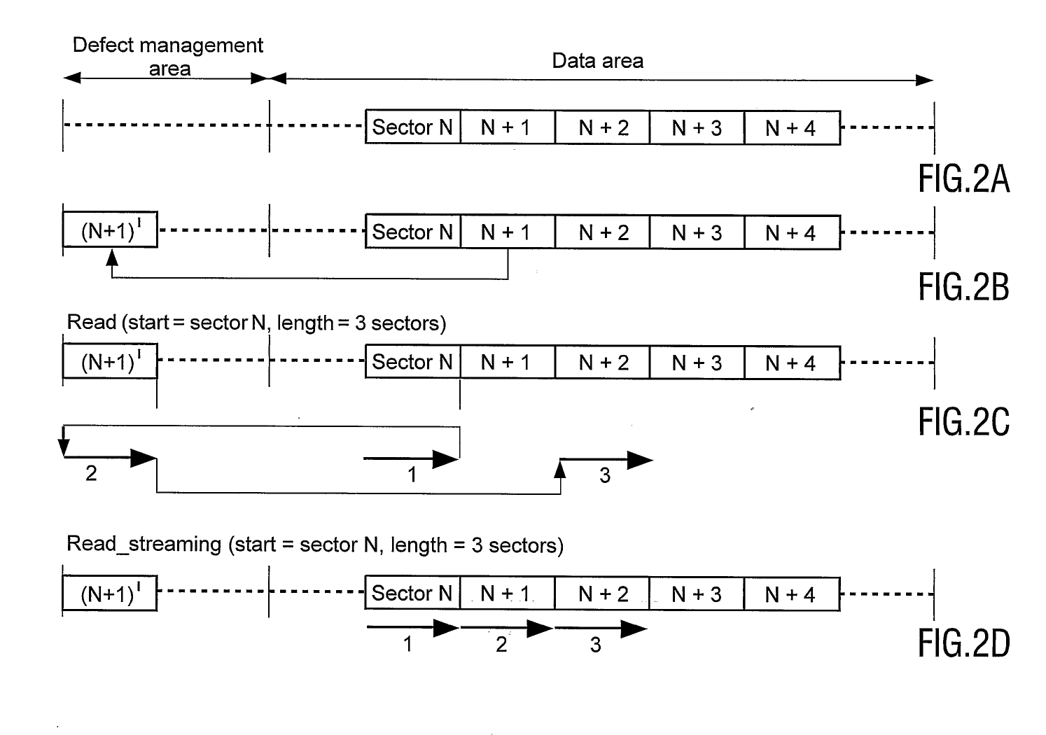

FIG. 2 shows graphs of the logical sector layout according to the invention,

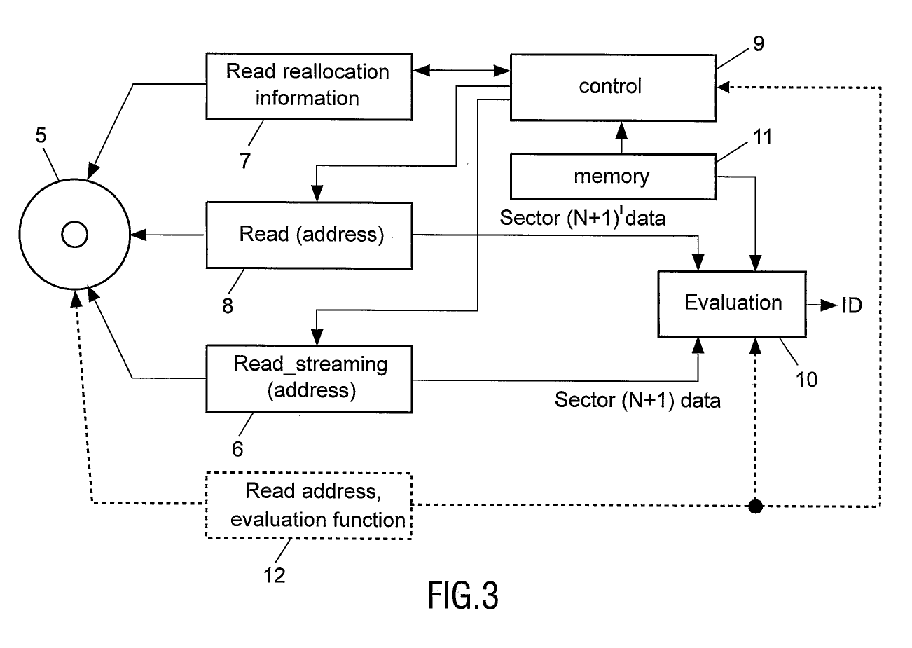

FIG. 3 shows a block diagram of a reproduction apparatus according to the invention, and

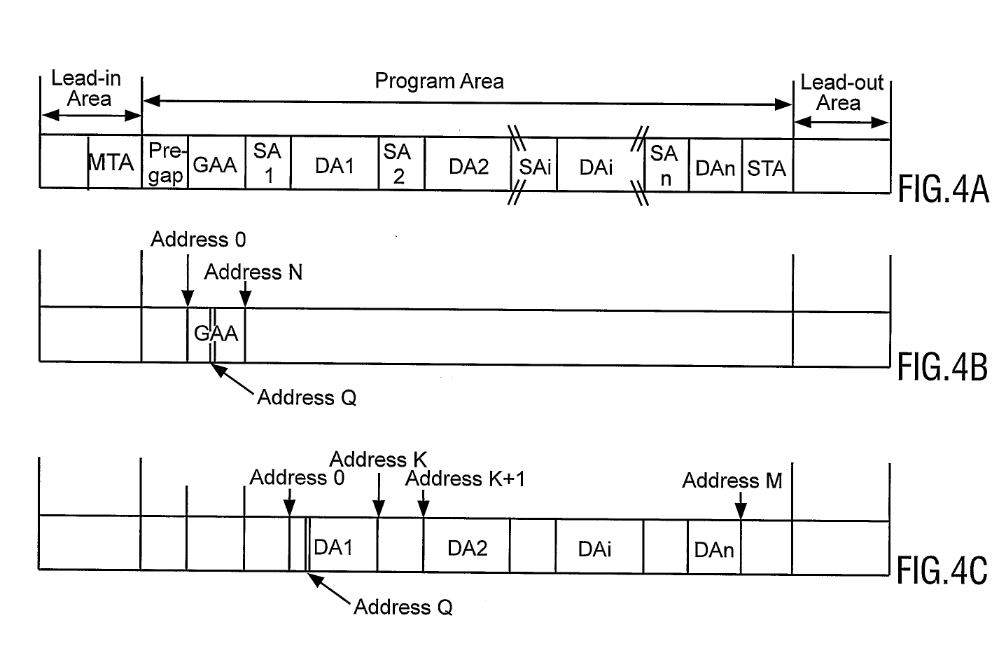

FIG. 4 shows graphs illustrating the sector layout according to another embodiment of the invention.

FIG. 1 schematically shows the main elements of a recording apparatus according to the present invention. It comprises a first recording unit 1 for recording data in the data area of the optical record carrier 5, a second recording unit 2 for recording data in the defect management area of the record carrier 5, a recording unit 3 for recording a reallocation information in the defect management area and a control unit 4 for controlling the recording units 1, 2, 3. Unlike conventional rewritable drives, Mount Rainier-compliant rewritable drives also support defect management. This means that when the program tries to write sector on the disc 5, which turns out to be a defective sector, that sector will be hidden and spare sectors will be used instead. So unlike normal packet writing, the error handling is done by the drive itself (i.e. by the hardware) instead of by the software. A schematical layout of the defect management area and of the data area of the disc 5 is shown in FIG. 2A, where further a number of sectors N to N+4 are shown in the data area.

In order to provide a unique identifier on the disc 5 it is now proposed according to the present invention that in a first step at least one data unit is stored in a sector of the data area, for instance in the sector N+1. As a next step this sector will be reallocated to the defect management area, i.e. the sector N+1 of the data area will be regarded and marked as defective (although this sector is physically non-defective) by writing a corresponding reallocation information into a so-called defect management table, also stored in the defect management area, preferably in the lead-in area of the disc 5 (not shown in FIG. 2). In the spare sector (N+1)′ located in the defect management area to which the original sector N+1 has been reallocated a second data unit will be recorded being different from the first data unit stored in the original sector N+1. This is schematically shown in FIG. 2B.

A reproduction apparatus which is schematically shown in the block diagram of FIG. 3 will now be able to reproduce the unique identifier as follows. By a first reading unit 6 the first data unit is read from the original sector of the data area (i.e. from sector N+1 in the example shown in FIG. 2B). The address of this sector is either predetermined and agreed upon between the reproduction apparatus and the recording apparatus (e.g. fixed in a standard), i.e. stored in a memory 11, or a corresponding address information is provided at a particular location on the disc 5 and read by a reading unit 12 beforehand.

In a next step a reallocation information is read by a second reading unit 7 from the disc 5, in particular from the defect management table, in order to retrieve the information to which sector of the defect management area the original first sector (N+1) has been reallocated. By use of this reallocation information another reading unit 8 then reads a second data unit from the reallocated sector of the defect management area (i.e. the content of sector (N+1)′ of the defect management area). All reading units are controlled by a control unit 9 to which the reallocation information is provided for appropriate control of the reading unit 8 which needs to know the address of the reallocated sector.

In an embodiment the second data unit can be read by use of a logical read command as shown in FIG. 2C. Sectors N through N+2 are read by use of such a logical read command. The data returned are the contents of sectors N, (N+1)′ and N+2 since sector N+1 is marked as defective so that a logical read command will instead read the contents of the spare sector (N+1)′.

The content of original sector N+1 can, for instance, be read by a streaming read command as shown in FIG. 2D. The data returned to a streaming read command to read the sectors N through N+2 are the contents of sectors N, N+1 and N+2.

In an evaluation unit 10 the first and second data units, i.e. the contents of the read sectors N+1 and (N+1)′, are evaluated by comparison and/or combination in order to obtain the unique identifier ID. For such evaluation different possibilities exist. For instance, the data could simply be subjected to an arithmetic or Boolean operation or to any scrambling algorithm. Another possibility is that one of the data units is interpreted as a decryption key for decryption of the other data unit, or as a pointer to point to a particular position within the other data unit at which the ID is stored. Even further, one of the data units could simply be ignored while the other data unit is processed or even taken as it is as ID. Of course, the way of evaluation and the algorithm used for evaluation have to agreed upon with the recording apparatus where the complementary evaluation algorithm has been used for providing the first and second data units on the disc 5. Thus, an information about this evaluation algorithm can either be stored on the disc 5 for read out by the reading unit 12, or it can be stored in the memory 11 of reproduction apparatus in advance.

Instead of using the contents of the sectors at the original position and the reallocation position, also the reallocation pattern can be used to extract the unique identifier. This can be done in many ways, but as a simple example a number of sectors (or ECC-blocks) at e.g. location N+n·512 (with n=0,1,2, . . . ) is either reallocated or not. If it is reallocated, this is a first bit value, otherwise it is a second bit value. Whether the user data in the original position differ from the user data in the reallocated position, can be determined by the difference between the reallocated sectors (ECC-blocks), for instance by issuing a logical read command and a streaming read command as shown in FIGS. 2C and 2D. Another method is to look into the copy of the reallocation tables, which are sometimes provided on the record carrier and available to the user under particular conditions. This can be seen in FIG. 4A showing the logical structure of a disc having a lead-in area, a program area and a lead-out area. As can be seen there is provided a main table area MTA in the lead-in area, particularly for storage of a defect management table including the reallocation information. A copy of this main table area is stored at the end of the program area as secondary table area STA.

Another method, particularly within the Mount Rainier format, is to make use of the GAA area (also shown in FIG. 4A) and the defect management area. A Mount Rainier drive can switch between GAA addressing and defect management area addressing. In GAA addressing, only the first small part of the program area can be accessed; the logical address space starts with sector 0 (see FIG. 4B). Without a special remapper, this part is the only part that a legacy drive can access. Instead, the defect management area has another addressing method; here, the logical address space also starts with sector 0. Logical block numbers address the user data blocks in the data area; only the run-in, run-out and link blocks are excluded (see FIG. 4C).

A logical read command to read sector Q can thus result in a physical read to a sector in the GAA part (in case of GAA addressing, see FIG. 4B) or to a sector in the defect management area part (in case of defect management area addressing, see FIG. 4C), depending on the setting of the addressing method in the Mount-Rainier drive.

Sectors with part of the information for deriving the unique identifier can thus be put in the same logical sectors of the two different areas. It can thus only be retrieved if the disc is inserted in an appropriate drive which is switched between the two addressing methods in order to retrieve both parts of the information needed to retrieve the unique identifier.

The present invention makes use of the defect management system in the drive and provides a possibility to store a unique identifier on an optical record carrier which can not easily be copied by a user.

1. Reproduction apparatus for reproducing a unique identifier ID from a record carrier (5), said record carrier having a data area for storing data and a defect management area for storing data reallocated from defective sectors of said data area and for storing reallocation information, comprising:
a reallocation information reading means (7) for reading a reallocation information from said defect management area marking a first predetermined non-defective sector in said data area as defective and as reallocated to a second sector in said defect management area,
a data reading means (6, 8) for reading a first data unit from said first sector and for reading a second data unit from said second sector, and
an evaluation means (10) for evaluating said first data unit and said second data unit by comparison and/or combination and for deriving said unique identifier ID from the result of said evaluation.

2. Reproduction apparatus as claimed in claim 1, wherein said evaluation means (10) is operative for deriving said unique identifier ID by combination of said first data unit and said second data unit according to a predetermined combination algorithm, in particular by an arithmetic or Boolean operation or a scrambling algorithm.

3. Reproduction apparatus as claimed in claim 1, wherein said evaluation means (10) is operative for deriving said unique identifier ID by use of one of said first or second data units as a pointer to point to a particular position within the other data unit at which the unique identifier ID is stored.

4. Reproduction apparatus as claimed in claim 1, wherein said evaluation means (10) is operative for deriving said unique identifier ID by use of one of said first or second data units as a decryption key to decrypt the other data unit giving said unique identifier ID.

5. Reproduction apparatus as claimed in claim 1, wherein said data reading means (6, 8) is operative for reading a plurality of first data units from a plurality of first sectors and for reading a plurality of second data units from a plurality of second sectors, and
wherein said evaluation means (10) is operative for deriving said unique identifier ID by comparing said first data units with the respective second data units and for obtaining said unique identifier ID from the result of said comparison.

6. Reproduction apparatus as claimed in claim 1, further comprising a memory means (11) for storing the logical address of said first and said second data unit and for storing the evaluation function to be used for evaluating said first data unit and said second data unit.

7. Reproduction apparatus as claimed in claim 1, further comprising an evaluation information reading means (12) for reading the logical address of said first and said second data unit and for reading the evaluation function to be used for evaluating said first data unit and said second data unit from said optical record carrier.

8. Reproduction apparatus as claimed in claim 1, wherein said data reading means (6, 8) are operative for reading said first data unit from said first sector by a streaming read command and for reading said second data unit from said second sector by a logical read command.

9. Reproduction apparatus as claimed in claim 1, wherein said data area is a general application area (GAA).

10. Reproduction method for reproducing a unique identifier ID from a record carrier (5), said record carrier having a data area for storing data and a defect management area for storing data reallocated from defective sectors of said data area and for storing a reallocation information, comprising the steps of:
reading a first data unit from a first predetermined non-defective sector in said data area,
reading a reallocation information from said defect management area marking said first sector in said data area as defective and as reallocated to a second sector in said defect management area,
reading said a second data unit from said second sector,
evaluating said first data unit and said second data unit by comparison and/or combination, and
deriving said unique identifier ID from the result of said evaluation.

11. Recording apparatus for recording a unique identifier ID on a record carrier (5), said record carrier having a data area for storing data and a defect management area for storing data reallocated from defective sectors of said data area and for storing a reallocation information, comprising:
a recording means (1, 2) for recording a first data unit at a first non-defective sector in said data area and for recording a second data unit at a second sector in said defect management area, and
a reallocation means (3) for recording a reallocation information in said defect management area marking said first sector as defective and as reallocated to said second sector, said first data unit and said second data unit being provided for evaluation by comparison and/or combination and for deriving said unique identifier ID from the result of said evaluation.

12. Recording method for recording a unique identifier ID on an optical record carrier (5), said optical record carrier having a data area for storing data and a defect management area for storing data reallocated from defective sectors of said data area and for storing reallocation information, comprising the steps of:
recording a first data unit at a first non-defective sector in said data area
recording a second data unit at a second sector in said defect management area, and
recording a reallocation information in said defect management area marking said first sector as defective and as reallocated to said second sector, said first data unit and said second data unit being provided for evaluation by comparison and/or combination and for deriving said unique identifier ID from the result of said evaluation.

13. Record carrier (5) having:
a data area for storing data including a first data unit stored at a first non-defective sector,
a defect management area for storing data reallocated from defective sectors of said data area, said data including a second data unit stored at a second sector, and for storing reallocation information including an information marking said first sector as defective and as reallocated to said second sector, said first data unit and said second data unit being provided for evaluation by comparison and/or combination and for deriving said unique identifier ID from the result of said evaluation.

14. Record carrier (5) as claimed in claim 13, wherein said record carrier is of the Mount Rainier format.

15. Computer program comprising program code means for causing a computer to perform the steps of the methods as claimed in claim 10 when said computer program is executed on a computer.
